(19) United States
(12) Patent Application Publication
(10) Pub. No.: US 2019/0363103 A1
(43) Pub. Date: Nov. 28, 2019

(54) IRREGULAR SHAPE DISPLAY PANEL

(71) Applicant: WUHAN CHINA STAR OPTOELECTRONICS TECHNOLOGY CO., LTD., Wuhan, HB (CN)

(72) Inventor: Yuejun Tang, Wuhan (CN)

(21) Appl. No.: 16/300,050

(22) PCT Filed: Sep. 22, 2018
(86) PCT No.: PCT/CN2018/107148

§ 371 Date: Nov. 8, 2018

(30) Foreign Application Priority Data
May 22, 2018 (CN) 201810495942.X

(51) Int. Cl. H01L 27/12; H05K 1/02; H05K 1/18; F21K 9/00

(52) U.S. Cl. CPC H01L 27/124; H05K 1/028; H05K 1/189; H05K 2201/056; F21K 9/00; H05K 2201/10128; H01L 27/1218

(57) ABSTRACT

An irregular shape display panel is disclosed. An upper terminal of the irregular shape display panel has a rectangular longitudinal groove formed by an opening/notch design, and a solder pad region is disposed in the groove. The solder pad region is provided with a connection terminal, and the connection terminal is electrically connected to a driving chip and a flexible circuit board. The flexible circuit board is bent to a back surface of the display panel. The driving chip is packaged by a chip-on-film (COF) method to be pressed and connected on the flexible circuit board, or the driving chip is packaged by a chip-on-glass (COG) method to be pressed and connected on a circuit bonding region of a peripheral region of the connection terminal. The irregular shape display panel of the invention can effectively reduce the width of the lower frame and increase panel proportion in terminal application.

### FIELD OF THE INVENTION

The present invention relates to a display technology field, and more particularly to an irregular shape display panel.

### BACKGROUND OF THE INVENTION

With the expansion of display product applications, companies that produce display panels or use display panels have begun to design and produce irregular shape display panel products, such as the IponeX mobile phone with an open/notch design. However, in the irregular shape display panel with open/notch design, the width of the lower frame is not reduced. The disposition of the opening/notch location makes some user think that the actual effective area or panel ratio does not increase, which affects the sales of the terminal products to some extent.

As shown in FIG. 1, it is a schematic structural layout diagram of a conventional irregular shape display panel. The display panel 10 has the opening/notch design, and mainly includes a solder pad region 20, an LED light bar 30, and a rectangular groove 40 formed at the opening/notch location. Edges of the panel 10 around the groove 40 can be respectively represented as a lateral edge A, a longitudinal edge B, a lateral edge C, a longitudinal edge D and a lateral edge E. The solder pad region 20 is provided a connection terminal 50, the flexible circuit board (FPC) 60 is connected to the connection terminal 50 of the solder pad region 20. The solder pad region 20 of the conventional irregular shape display panel is disposed at a lower end of the display panel 10, and the LED strip 30 in the backlight system is also disposed at the same end of the display panel 10 as the solder pad region 20. In FIG. 1, the LED strip 30 can also be disposed at a side of one end of the solder pad region 20, and is located below the display panel 10. The LED strip 30 can also be located below a lower substrate of the display panel 10, and is not necessarily located horizontally below the display panel 10 in FIG. 1. Since both of the solder pad region 20 and the LED strip 30 occupy the width of the lower frame of the display panel 10, the lower frame is wider.

### SUMMARY OF THE INVENTION

Accordingly, an object of the present invention to provide an irregular shape display panel that reduces the lower frame of the panel.

In order to achieve the above purpose, the present invention provides an irregular shape display panel, wherein an upper terminal of the irregular shape display panel has a rectangular longitudinal groove formed by an opening/notch design, and a solder pad region is disposed in the groove.

Wherein the solder pad region is provided with a connection terminal, and the connection terminal is electrically connected to a driving chip and a flexible circuit board.

Wherein the flexible circuit board is bent to a back surface of the display panel.

Wherein driving chip is packaged by a chip-on-film (COF) method to be pressed and connected on the flexible circuit board, or the driving chip is packaged by a chip-on-glass (COG) method to be pressed and connected on a circuit bonding region of a peripheral region of the connection terminal.

Wherein the irregular shape display panel further comprises an LED light bar, and the LED light bar is disposed at a side edge along a lower edge of the display panel or disposed below a lower substrate of the display panel along the lower edge of the display panel.

Wherein the irregular shape display panel further comprises an LED light bar, and the LED light bar is disposed at a same side of the groove.

Wherein the LED light bar is disposed at a side edge along longitudinal edges of two sides of the groove and edges of the solder pad region or the LED light bar is disposed below the lower substrate of the display panel along the longitudinal edges of the groove and the edges of the solder pad region.

Wherein the LED light bar is disposed at a side edge along an upper edge of the display panel at two sides of the groove, longitudinal edges of the groove and an edge of the solder pad region; or the LED light bar is disposed below the lower substrate of the display panel along an upper edge of the display panel at two sides of the groove, longitudinal edges of the groove and an edge of the solder pad region.

Wherein the LED light bar is disposed at a side edge along an upper edge of the display panel at two sides of the groove and an edge of the solder pad region; or, the LED light bar is disposed below a lower substrate of the display panel along an upper edge of the display panel at two sides of the groove and an edge of the solder pad region.

Wherein the gate driving circuit is distributed at left and right frame position of the display panel, wherein the gate driving circuit at the left and right frame position respectively connect to the connection terminal of the solder pad region through a gate driving circuit trace at an upper edge of the display panel.

Wherein the scanning lines located at two sides of the groove are respectively connected to the gate driving circuit at a same side, odd/even row scanning lines disposed below the groove are respectively connected to the gate driving circuit at different sides, or simultaneously connected to the gate driving circuit at two sides.

Wherein the data lines located at two sides of the groove are connected to the connection terminal of the solder pad region by traces located at the upper edge of the display panel at two sides of the groove and longitudinal edges at two sides of the groove; the data line located below the groove are connected to the connection terminal of the solder pad region at a position of a lateral edge of the bottom portion of the groove.

In summary, the irregular shape display panel of the present invention can effectively reduce the width of the lower frame of the panel; and increase the proportion of the display panel in the terminal application.

### BRIEF DESCRIPTION OF THE DRAWINGS

The technical solutions and other advantageous effects of the present invention will be apparent from the following detailed description of embodiments of the invention.

In the figures,

FIG. 1 is a schematic structural layout diagram of a conventional irregular shape display panel.

FIG. 2 is a schematic structural layout diagram of an irregular shape display panel according to a first embodiment of the present invention.

FIG. 3 is a schematic diagram of a trace distribution of a gate driving related signal line/gate driving circuit of the irregular shape display panel of the present invention.

FIG. 4 is a schematic diagram of a trace distribution of the data lines of the irregular shape display panel of the present invention.

FIG. 5 is a schematic structural layout diagram of the irregular shape display panel according to a second embodiment of the present invention.

FIG. 6 is a schematic structural layout diagram of the irregular shape display panel according to a third embodiment of the present invention.

FIG. 7 is a schematic structural layout diagram of the irregular shape display panel according to a fourth embodiment of the present invention.

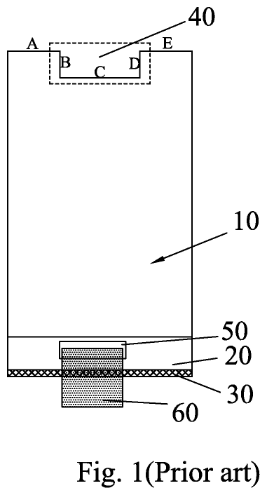

### DETAILED DESCRIPTION OF PREFERRED EMBODIMENTS

Based on the problems raised by the background art, the present invention proposes a design for reducing a lower frame of the irregular shape display panel and increasing the panel proportion in the terminal application, that is, the solder pad region is disposed in the groove of the opening/notch; furthermore, using the glass flip chip or flip chip technology to connect the pad region to the control circuit system (which can include driver chip, flexible board, and printed circuit board); the flexible board can be bent to a rear of the display panel; and the LED strips of the backlight system can be disposed to an opposite side or the same side of the opening/notch.

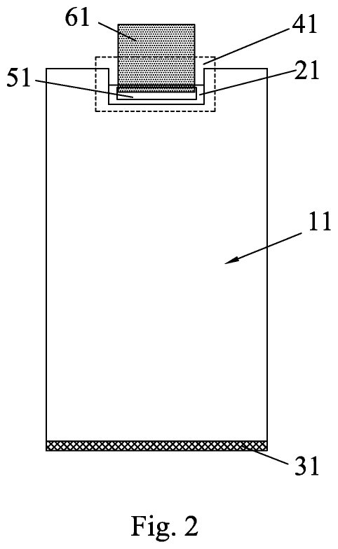

Referring to FIG. 2, it is a schematic structural layout diagram of the irregular shape display panel of a first embodiment of the present invention. An upper terminal of the display panel 11 has a rectangular longitudinal groove 41 formed by an opening/notch design. A rectangular solder pad region 21 is disposed in the groove 41 along a lateral edge of a bottom portion of the groove 41. In this embodiment, the solder pad region 21 of the display panel 11 is disposed in the groove 41 of the opening/notch position. A surface of the solder pad region 21 is provided with a connection terminal 51, and the solder pad region 21 is electrically connected to a driving chip (not shown) and a flexible circuit board 61 through the connection terminal 51. The flexible circuit board 61 can further electrically connect to a printed circuit board (not shown), and a control circuit system including the driving chip, the flexible circuit board 61 and the printed circuit board is used for inputting and controlling related signals so that the display panel 11 can display a desired image.

At this time, it is preferable that the driving chip is packaged by a chip-on-film (COF) method, that is, the driving chip is pressed and connected on the flexible circuit board 61, and the flexible circuit board 61 is bent to a back surface of the display panel 11, so that the display panel 11 can have a minimum frame width at the opening/notch position. At the same time, in the present invention, the driving chip can also be packaged by a chip-on-glass (COG) method, that is, the driving chip is pressed and connected on a circuit bonding region of a peripheral region of the connection terminal 51. In this embodiment, an LED light bar 31 of a backlight system is disposed at an opposite side of the opening/notch position, that is, the groove 41. That is, the LED light bar 31 is not disposed at the groove position; the LED light bar 31 can be disposed at a side edge along a lower edge of the display panel 11, and also can be disposed below a lower substrate of the display panel 11 along the lower edge of the display panel 11 so that the display panel can have a narrower frame width.

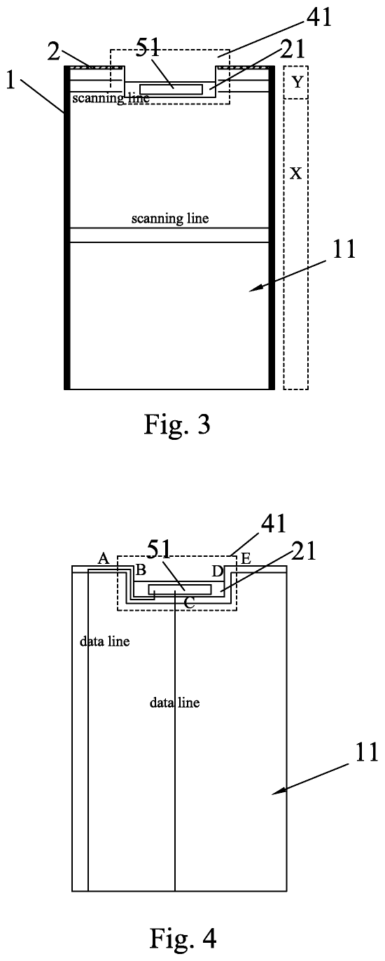

Referring to FIG. 3, it is a schematic diagram of a trace distribution of a gate driving related signal line/gate driving circuit of the irregular shape display panel of the present invention. The black bold line in FIG. 3 illustrates the arrangement of the gate driving circuit 1. The gate driving circuit 1 is distributed at left and right frame position of the display panel 11, wherein the gate driving circuit 1 at the left and right frame position respectively connects to the connection terminal 51 of the solder pad region 21 through a gate driving circuit trace 2 at an upper edge of the display panel 11. The gate driving circuit trace 2 can include related signal lines of the gate driving circuit 1 such as Vgh/Vgl/clock signal line or the like.

The gate driving circuit 1 can sequentially transmit a signal to drive scanning lines connected to the Y/X portion, and the scanning lines connected to the Y portion corresponds to the row scanning lines located at two sides of the groove 41, and the scanning lines connected to the X portion corresponds to the scanning lines located below the groove 41. The gate driving circuit 1 may be in the form of gate driver on array (GOA) circuit. According to the specific structure and driving mode of the GOA circuit, the odd/even row scanning lines in the Y portion of FIG. 3 may be connected to a same side GOA circuit. It can also be driven separately from both sides; the odd/even row scanning lines in the X portion can be respectively connected to the GOA circuits at different sides, can be interlaced driven, or can be connected to the GOA circuits at two sides at the same time, and can be driven simultaneously from the two sides.

Referring to FIG. 4, it is a schematic diagram of the trace distribution of the data lines of the irregular shape display panel of the present invention. The data lines located at two sides of the groove 41 are connected to the connection terminal 51 of the solder pad region 21 by the traces located at the upper edge A (or E) of the display panel 11 at two sides of the groove 41 and longitudinal edges B (or D) at two sides of the groove 41. That is, the direction of the trace may be along the edge AB or DE, or the direction of the trace in FIG. 4 may be along the edge ABC or CDE. The data line located below the groove 41 are connected to the connection terminal 51 of the solder pad region 21 at a position of a lateral edge C of the bottom portion of the groove 41.

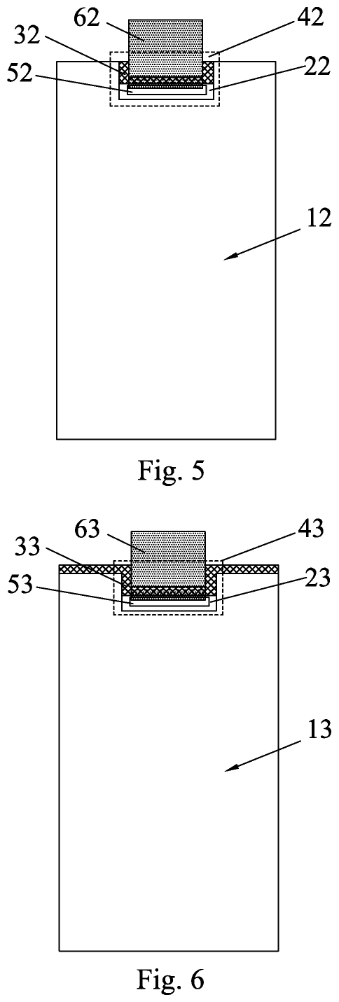

FIG. 5 is a schematic structural layout diagram of the irregular shape display panel according to a second embodiment of the present invention. An upper terminal of the display panel 12 has a rectangular longitudinal groove 42 formed by an opening/notch design. A rectangular solder pad region 22 is disposed in the groove 41 along a lateral edge of a bottom portion of the groove 42. A surface of the solder pad region 22 is provided with a connection terminal 52, and the solder pad region 22 is electrically connected to a flexible circuit board 62 through the connection terminal 52. The difference between the second embodiment and the first embodiment is that the position of the LED light bar 32 of the backlight system is different, and the LED light bar 32 is disposed on the same side of the groove 42. The LED light bar 32 is disposed at a side edge along longitudinal edges of two sides of the groove 42 and edges of the solder pad region 22. In other embodiments, the LED light bar 32 is disposed below the lower substrate of the display panel 12 along the longitudinal edges of the groove 42 and the edges of the solder pad region 22.

FIG. 6 is a schematic structural layout diagram of the irregular shape display panel of a third embodiment of the present invention. The upper end of the panel 13 has a rectangular longitudinal groove 43 formed by an opening/notch design, and a rectangular pad region 23 disposed in the groove 43 along the bottom lateral edge of the groove 43. The surface of the solder pad region 23 is provided with a connection terminal 53, and the pad region 23 is electrically connected to the flexible circuit board 63 through the connection terminal 53. The LED light bar 33 is disposed at a side edge along an upper edge of the display panel 13 at two sides of the groove 43, longitudinal edges of the groove 43 and an edge of the solder pad region 23. In other embodiments, the LED light bar 33 can also be disposed below the lower substrate of the display panel 13 along an upper edge of the display panel 13 at two sides of the groove 43, longitudinal edges of the groove 43 and an edge of the solder pad region 23.

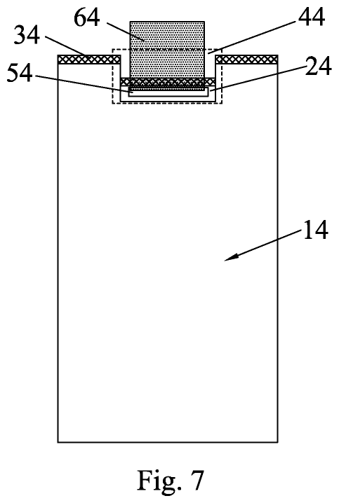

FIG. 7 is a schematic structural layout diagram of the irregular shape display panel of a third embodiment of the present invention. The upper terminal of the display panel 14 has a rectangular longitudinal groove 44 formed by an opening/notch design, and a rectangular pad region 24 disposed in the groove 44 along a lateral edge of the bottom portion of the groove 44. The surface of the solder pad region 24 is provided with a connection terminal 54, and the solder pad region 24 is electrically connected to the flexible circuit board 64 through the connection terminal 54. The LED light bar 34 is disposed at a side edge along an upper edge of the display panel 14 at two sides of the groove 44 and an edge of the solder pad region 24. In other embodiments, the LED light bar 34 can also be disposed below a lower substrate of the display panel 13 along an upper edge of the display panel 14 at two sides of the groove 44 and an edge of the solder pad region 24.

In the second/third/fourth embodiment, with the appropriate dot arrangement of the light guide plate in backlight system, the present invention can make the brightness of the display panel meet the uniformity requirement.

In other preferred embodiments of the irregular shape display panel of the present invention, the irregular shape display panel may also be a panel type such as an OLED panel that does not require a backlight system. In such a panel, the solder pad region may be disposed at an opening/notch position, and may be adopted COF or COG bonding/connection solution, and with flexible FPC bent to the back side of the open/opened hole substrate.

In summary, the irregular shape display panel of the present invention can effectively reduce the width of the lower frame of the panel; and increase the proportion of the display panel in the terminal application.

In the above, for those of ordinary skill in the art, various other changes and modifications can be made in accordance with the technical solutions and technical concept of the present invention, and all such changes and modifications are intended to be included within the scope of the appended claims.

What is claimed is:

1. An irregular shape display panel, wherein an upper terminal of the irregular shape display panel has a rectangular longitudinal groove formed by an opening/notch design, and a solder pad region is disposed in the groove.

2. The irregular shape display panel according to claim 1, wherein the solder pad region is provided with a connection terminal, and the connection terminal is electrically connected to a driving chip and a flexible circuit board.

3. The irregular shape display panel according to claim 2, wherein the flexible circuit board is bent to a back surface of the display panel.

4. The irregular shape display panel according to claim 2, wherein driving chip is packaged by a chip-on-film (COF) method to be pressed and connected on the flexible circuit board, or the driving chip is packaged by a chip-on-glass (COG) method to be pressed and connected on a circuit bonding region of a peripheral region of the connection terminal.

5. The irregular shape display panel according to claim 1, wherein the irregular shape display panel further comprises an LED light bar, and the LED light bar is disposed at a side edge along a lower edge of the display panel or disposed below a lower substrate of the display panel along the lower edge of the display panel.

6. The irregular shape display panel according to claim 1, wherein the irregular shape display panel further comprises an LED light bar, and the LED light bar is disposed at a same side of the groove.

7. The irregular shape display panel according to claim 6, wherein the LED light bar is disposed at a side edge along longitudinal edges of two sides of the groove and edges of the solder pad region or the LED light bar is disposed below the lower substrate of the display panel along the longitudinal edges of the groove and the edges of the solder pad region.

8. The irregular shape display panel according to claim 6, wherein the LED light bar is disposed at a side edge along an upper edge of the display panel at two sides of the groove, longitudinal edges of the groove and an edge of the solder pad region; or the LED light bar is disposed below the lower substrate of the display panel along an upper edge of the display panel at two sides of the groove, longitudinal edges of the groove and an edge of the solder pad region.

9. The irregular shape display panel according to claim 6, wherein the LED light bar is disposed at a side edge along an upper edge of the display panel at two sides of the groove and an edge of the solder pad region; or, the LED light bar is disposed below a lower substrate of the display panel along an upper edge of the display panel at two sides of the groove and an edge of the solder pad region.

10. The irregular shape display panel according to claim 1, wherein the gate driving circuit is distributed at left and right frame position of the display panel, wherein the gate driving circuit at the left and right frame position respectively connect to the connection terminal of the solder pad region through a gate driving circuit trace at an upper edge of the display panel.

11. The irregular shape display panel according to claim 10, wherein the scanning lines located at two sides of the groove are respectively connected to the gate driving circuit at a same side, odd/even row scanning lines disposed below the groove are respectively connected to the gate driving circuit at different sides, or simultaneously connected to the gate driving circuit at two sides.

12. The irregular shape display panel according to claim 1, wherein the data lines located at two sides of the groove are connected to the connection terminal of the solder pad region by traces located at the upper edge of the display panel at two sides of the groove and longitudinal edges at two sides of the groove; the data line located below the groove are connected to the connection terminal of the solder pad region at a position of a lateral edge of the bottom portion of the groove.
